(19) United States
(12) Patent Application Publication
(10) Pub. No.: US 2026/0288166 A1
(43) Pub. Date: Sep. 24, 2026

(54) TRANSPORT SYSTEM

(71) Applicant: Murata Machinery, Ltd., Kyoto-shi, Kyoto (JP)

(72) Inventor: Kazumi HARASAKI, Kyoto-shi (JP)

(21) Appl. No.: 19/475,580

(22) PCT Filed: Jan. 10, 2024
(86) PCT No.: PCT/JP2024/000313

§ 371 Date: Oct. 15, 2025

(30) Foreign Application Priority Data
Apr. 17, 2023 (JP) 2023-066930

(51) Int. Cl. G05D 1/69; G05D 105/20

(52) U.S. Cl. CPC G05D 1/69; G05D 2105/20

(57) ABSTRACT

A travel route includes a merging portion where a first route and a second route merge. A controller executes one of priority control to cause a transport vehicle traveling on one of the first route and the second route set as a priority route to preferentially pass through the merging portion with respect to a transport vehicle traveling on the other route, and non-priority control to cause a transport vehicle to pass through the merging portion without giving priority depending on whether the transport vehicle is traveling on the first route or the second route, executes the non-priority control when congestion of a transport vehicle occurs in a predetermined determination target area located on an upstream side of the merging portion in the first route or the second route, and executes the priority control when congestion of a transport vehicle does not occur in the determination target area.

### BACKGROUND OF THE INVENTION

### 1. Field of the Invention

The present disclosure relates to transport systems.

### 2. Description of the Related Art

As described in WO 2010/035411 A, there is known a transport system (transport vehicle system) including a travel route having a first route, a second route having a standby portion, and a merging portion where the first route and the second route merge, a plurality of transport vehicles traveling on the travel route, and a controller that controls travel of the plurality of transport vehicles. In this transport system, a transport vehicle traveling on the first route is caused to continuously pass through the merging portion while a transport vehicle traveling on the second route is caused to wait at the standby portion until a predetermined number of transport vehicles stop at the standby portion of the second route.

### SUMMARY OF THE INVENTION

In the above-described conventional system, a transport vehicle stops at the standby portion of the second route until a predetermined number of transport vehicles stop at the standby portion. When a standby time of the transport vehicle at the standby portion is excessive, the transport vehicle stays at the standby portion for a long time, and therefore transport efficiency decreases. In order to prevent the standby time of the transport vehicle at the standby portion from becoming excessive, it is conceivable to set a limit on the standby time and to execute control (DLE: Dead Lock Escape) in which a transport vehicle whose standby time is a predetermined time or longer is caused to travel on another travel route to bypass the merging portion. However, the transport vehicle bypasses the merging portion, whereby a traveling distance of the transport vehicle increases, and as a result, transport efficiency decreases.

In view of such a problem, it is conceivable that the controller executes control to cause a transport vehicle traveling on the first route and a transport vehicle traveling on the second route to alternately pass through the merging portion, thereby suppressing an occurrence of the transport vehicle staying at the standby portion. However, the transport vehicle repeats starting and stopping, and as a result, transport efficiency decreases.

Example embodiments of the present invention describe transport systems capable of improving transport efficiency.

A transport system according to an example embodiment of the present disclosure includes a plurality of transport vehicles that travel on a travel route and transport an article, and a controller configured or programmed to control travel of the plurality of transport vehicles. The travel route includes a first route, a second route different from the first route, and a merging portion where the first route and the second route merge. The controller is configured or programmed to execute one of priority control to cause one of the plurality of transport vehicles traveling on one of the first route and the second route set as a priority route to preferentially pass through the merging portion with respect to another one of the plurality of transport vehicles traveling on the other route, and non-priority control to cause the one of the plurality of transport vehicles to pass through the merging portion without giving priority depending on whether the one of the plurality of transport vehicles is traveling on the first route or the second route. The controller is configured or programmed to execute the non-priority control when congestion of a transport vehicle occurs in a predetermined determination target area located on an upstream side of the merging portion in the first route or the second route, and execute the priority control when congestion of a transport vehicle does not occur in the determination target area.

In this transport system, when congestion of a transport vehicle occurs in the determination target area, the controller is configured or programmed to execute the non-priority control. In the non-priority control, a transport vehicle is caused to pass through the merging portion without being prioritized depending on a travel route on which the transport vehicle travels, and therefore, it is possible to eliminate congestion of a transport vehicle in the determination target area. In addition, in this transport system, when congestion of a transport vehicle does not occur in the determination target area, the controller is configured or programmed to execute the priority control. In the priority control, one transport vehicle traveling on one of the first route and the second route set as a priority route preferentially passes through the merging portion with respect to the other transport vehicle traveling on the other route. As a result, when one transport vehicle passes through the merging portion, the transport vehicle does not need to wait until the other transport vehicle passes through the merging portion. As a result, one transport vehicle can pass through the merging portion without repeating starting and stopping. From the above, transport efficiency is improved.

In the non-priority control, a transport vehicle traveling on the first route and a transport vehicle traveling on the second route may be caused to alternately pass through the merging portion. In this case, by causing a transport vehicle traveling on the first route and a transport vehicle traveling on the second route to alternately pass through the merging portion, it is possible to reliably eliminate congestion of a transport vehicle in the determination target area.

The controller may be configured or programmed to determine that congestion of a transport vehicle occurs in the determination target area when there are a predetermined number or more of transport vehicles spaced from transport vehicles located in front thereof by a predetermined distance or less in the determination target area. In this case, presence or absence of congestion of a transport vehicle can be determined on the basis of the number of transport vehicles approaching each other in the determination target area. As a result, it is possible to easily determine congestion of a transport vehicle in the determination target area.

A transport vehicle according to an example embodiment of the present invention includes a distance calculator configured or programmed to measure a distance to a transport vehicle located in front of its own vehicle, and a travel controller configured or programmed to cause the travel vehicle to stop when the distance is a predetermined distance or less. The controller may be configured or programmed to determine that congestion of a transport vehicle occurs in the determination target area when there are a predetermined number or more of transport vehicles stopped under control of the travel controller in the determination target area. In this case, presence or absence of congestion of a transport vehicle can be determined on the basis of the number of transport vehicles stopped under control of the travel controller in the determination target area. As a result, it is possible to more easily determine congestion of a transport vehicle in the determination target area.

The determination target area may include a connecting route connected to a merging portion and a plurality of merging routes merging into the connecting route. For example, when the connecting route does not have a sufficient length, it may be difficult to determine presence or absence of congestion only from a travel situation on the connecting route. By considering not only the connecting route but also the number of transport vehicles in the plurality of merging routes and the like, it is possible to accurately determine congestion regardless of a layout of the travel route.

According to example embodiments of the present disclosure, transport efficiency is improved.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is an overall schematic view of a transport system according to an example embodiment of the present invention.

FIG. 2 is a block diagram illustrating a functional configuration of a controller and a transport vehicle according to an example embodiment of the present invention.

FIG. 3 is a diagram illustrating one step in an operation of the transport system.

FIG. 4 is a diagram illustrating a step after the step illustrated in FIG. 3.

FIG. 5 is a diagram illustrating a step after the step illustrated in FIG. 4.

FIG. 6 is a diagram illustrating a step after the step illustrated in FIG. 5.

FIG. 7 is a diagram illustrating a step after the step illustrated in FIG. 6.

FIG. 8 is a diagram illustrating a step after the step illustrated in FIG. 7.

FIG. 9 is a diagram illustrating a step after the step illustrated in FIG. 8.

### DETAILED DESCRIPTION OF THE EXAMPLE EMBODIMENTS

Hereinafter, example embodiments of the present disclosure will be described with reference to the drawings. In description of the drawings, the same elements are denoted by the same reference numerals, and redundant description is omitted.

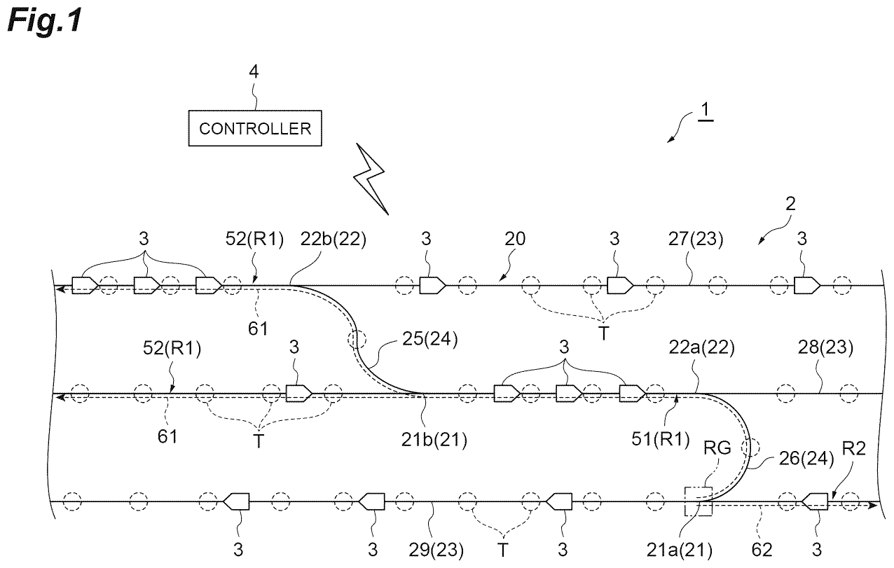

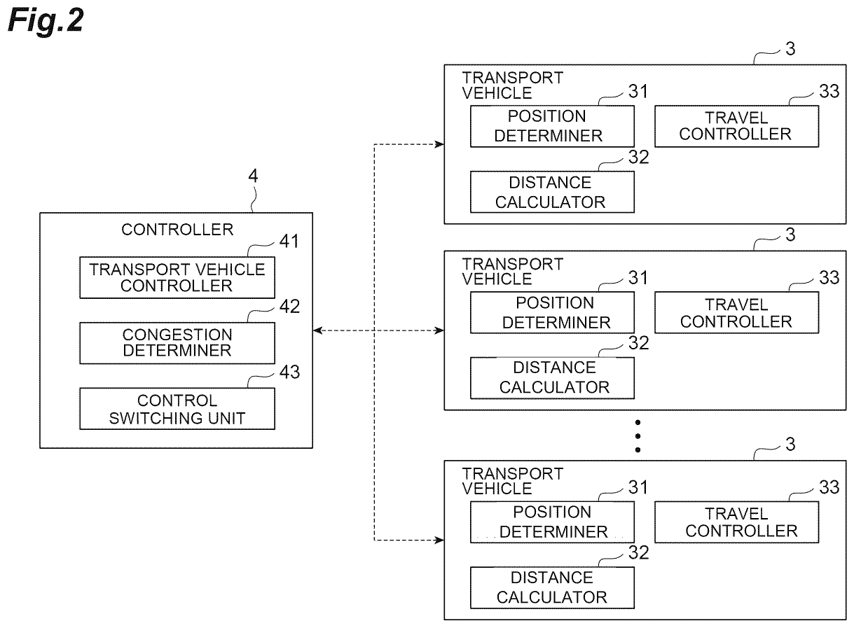

First, an outline of a transport system 1 will be described with reference to FIGS. 1 and 2. As illustrated in FIG. 1, the transport system 1 is a system that transports an article (not illustrated). The article is, for example, a container such as a front opening unified pod (FOUP) that stores a plurality of semiconductor wafers. The article may be a reticle pod that stores a glass substrate, other general components, or the like. The transport system 1 includes a track (travel route) 2, a plurality of transport vehicles 3, and a controller 4.

The track 2 is a predetermined travel path along which the transport vehicle 3 is able to travel. The track 2 is laid, for example, near a ceiling which is an overhead space of a worker. The track 2 is suspended from the ceiling via a plurality of supports (not illustrated), for example. The track 2 is formed by connecting a plurality of route portions 20 to each other. The track 2 includes a merging portion 21 where the plurality of route portions 20 merge and a branching portion 22 where one route portion 20 branches into the plurality of route portions 20. A layout (the shapes, lengths, and arrangement of the route portions 20, and the positions of the merging portion 21 and the branching portion 22) of the track 2 is not particularly limited, and various layouts can be adopted.

The plurality of route portions 20 includes, for example, a plurality of linear routes 23 and a plurality of curved routes 24. In the example illustrated in FIG. 1, the plurality of linear routes 23 includes a first linear route 27, a second linear route 28, and a third linear route 29 which are a plurality of parallel routes extending in a certain direction. The second linear route 28 is disposed between the first linear route 27 and the third linear route 29. Although not illustrated, as the entire track 2, there are a plurality of linear routes and the like extending in a direction other than this certain direction (for example, in a direction orthogonal to this certain direction). In the present specification, the terms “upstream side” and “downstream side” are used by using a traveling direction of the transport vehicle 3 as a reference.

The curved route 24 branches via a branching portion 22 in the middle of one linear route 23 and merges via a merging portion 21 in the middle of another linear route 23. The plurality of curved routes 24 includes an S-shaped route 25 and a U-shaped route 26. The S-shaped route 25 is a route for changing the linear route 23 on which the transport vehicle 3 travels without changing a traveling direction of the transport vehicle 3. In the present example embodiment, the S-shaped route 25 connects the first linear route 27 and the second linear route 28 to each other. The U-shaped route 26 is a route for changing the linear route 23 on which the transport vehicle 3 travels by changing the traveling direction of the transport vehicle 3. The U-shaped route 26 connects the second linear route 28 and the third linear route 29 to each other. In the example illustrated in FIG. 1, the U-shaped route 26 is located on a downstream side of the S-shaped route 25.

Hereinafter, a merging portion 21 where the U-shaped route 26 and the third linear route 29 merge may be referred to as a merging portion 21a, and a merging portion 21 where the S-shaped route 25 and the second linear route 28 merge may be referred to as a merging portion 21b. A branching portion 22 where the second linear route 28 branches into the U-shaped route 26 may be referred to as a branching portion 22a, and a branching portion 22 where the first linear route 27 branches into the S-shaped route 25 may be referred to as a branching portion 22b.

When the track 2 is described from a viewpoint different from the above description, the track 2 includes a first route R1, a second route R2 different from the first route R1, and a merging portion 21 where the first route R1 and the second route R2 merge. Each of the first route R1 and the second route R2 is a route located on an upstream side of the merging portion 21 and connected to the merging portion 21. The first route R1 merging into the merging portion 21a includes a connecting route 51 connected to the merging portion 21a and a plurality of merging routes 52 merging into the connecting route 51 at the merging portion 21b. The second route R2 merging into the merging portion 21a includes, for example, a portion of the third linear route 29 located on an upstream side of the merging portion 21a.

In the present example embodiment, the connecting route 51 includes the U-shaped route 26 and a portion of the second linear route 28 located on an upstream side of the branching portion 22a and located on a downstream side of the merging portion 21b. The plurality of merging routes 52 includes a portion of the second linear route 28 located on an upstream side of the merging portion 21b. The plurality of merging routes 52 includes an S-shaped route 25 and a portion of the first linear route 27 located on an upstream side of the branching portion 22b.

There are a plurality of stop points T, which are positions where the transport vehicle 3 is caused to stop, on the track 2. The stop points T are located at predetermined positions. The stop points T are set by using, for example, a plurality of point marks (not illustrated) such as barcodes attached so as to be aligned at regular intervals along the track 2 as a reference. In the drawing, the stop points T are indicated by dashed circles on the track 2.

The transport vehicle 3 travels in a traveling direction on the track 2 to transport an article. The transport vehicle 3 transports an article on the basis of, for example, a transport command assigned by the controller 4. The transport command includes, for example, information regarding transfer of an article at a transport source, travel along a route from the transport source to a transport destination, and transfer of an article at the transport destination. The transport vehicle 3 is configured to be able to transfer an article to and from a port (not illustrated) . The transport vehicle 3 is an overhead traveling unmanned traveling vehicle. The transport vehicle 3 is also referred to as, for example, a traveling vehicle, a transport carriage, or an overhead traveling vehicle (overhead traveling carriage). The number of transport vehicles 3 included in the transport system 1 is not particularly limited.

The transport vehicle 3 includes, for example, a traveling unit, a θ drive, a transverse feeding unit, an elevating drive unit, and an elevating stage (not illustrated). The traveling unit causes the transport vehicle 3 to travel along the track 2. The e drive turns the elevating drive unit in a horizontal plane to control an attitude of an article. The transverse feeding unit transversely feeds a portion below the e drive with respect to the track 2. The elevating drive unit lifts and lowers the elevating stage holding an article. The elevating stage has a chuck, and can freely hold or release an article. Note that the configuration of the transport vehicle 3 can be appropriately changed.

As illustrated in FIG. 2, the transport vehicle 3 includes a position determiner 31, a distance calculator 32, and a travel controller 33 as a functional configuration thereof. The position determiner 31 is configured or programmed to acquire position information indicating the position of the transport vehicle 3 on the track 2. The position determiner 31 includes, for example, a reader configured or programmed to read a point mark on the track 2 and an encoder. The position information includes, for example, information on a point mark obtained by the reading unit and information regarding a travel distance after passing through the point mark. The position determiner 31 is configured or programmed to transmit the acquired position information to the travel controller 33.

The distance calculator 32 is configured or programmed to measure e a distance between its vehicle (the transport vehicle 3 including the distance calculator 32) and a transport vehicle 3 located in front of its own vehicle. The front means the front in a traveling direction of the transport vehicle 3. The distance calculator 32 includes, for example, an inter-vehicle sensor configured or programmed to detect a distance between its own vehicle and a transport vehicle 3 present in front of its own vehicle. For example, the distance calculator 32 is configured or programmed to emit laser light toward the front of its own vehicle and detects reflected light reflected by a reflector of the transport vehicle 3 in front, to detect a distance between its own vehicle and the transport vehicle 3 in front of its own vehicle. The distance calculator 32 transmits the measured distance to the travel controller 33.

The travel controller 33 may include an electronic controller including a central processing unit (CPU), a read only memory (ROM), a random access memory (RAM), and the like. The travel controller 33 can be configured as, for example, software in which a program stored in the ROM is loaded onto the RAM and executed by the CPU. The travel controller 33 may be configured as hardware with an electronic circuit or the like.

The travel controller 33 is configured or programmed to control various operations of the transport vehicle 3. The travel controller 33 is configured or programmed to control the traveling unit and the distance calculator 32. The travel controller 33 can communicate with the controller 4. For example, the travel controller 33 may communicate with the controller 4 via a power supply line or the like of the track 2, or may communicate with the controller 4 via a communication line (feeder line or the like) disposed along the track 2 separately from the power supply line. When receiving a state inquiry from the controller 4, the travel controller 33 transmits a state report of its own vehicle to the controller 4.

The travel controller 33 determines whether or not a distance between its own vehicle and a transport vehicle 3 in front of its own vehicle is a predetermined distance or less on the basis of a detection result of the distance calculator 32. The predetermined distance is set in advance, for example, and can be appropriately changed. When the distance is a predetermined distance or less, the travel controller 33 is configured or programmed to execute stop control to cause its own vehicle to stop by controlling the traveling unit. The travel controller 33 is configured or programmed to transmit a state report including position information acquired by the position determiner 31 and information indicating that the stop control is being executed to the controller 4.

The travel controller 33 is configured or programmed to store a layout of the track 2 in advance. The layout of the track 2 includes information indicating the positions of the route portions 20, the merging portions 21, and the branching portions 22. The travel controller 33 determines whether or not its own vehicle is about to pass through the merging portion 21 on the basis of a traveling vehicle speed of its own vehicle set in advance, a layout of the track 2, and position information of its own vehicle. The travel controller 33 is configured or programmed to determine that its own vehicle is about to pass through the merging portion 21, for example, when its own vehicle reaches a position where a time required for traveling to the merging portion 21 is less than a predetermined time.

The travel controller 33 determines whether or not its own vehicle is about to pass through the branching portion 22 on the basis of a traveling vehicle speed of its own vehicle, a layout of the track 2, and position information of its own vehicle set in advance. The travel controller 33 is configured or programmed to determine that its own vehicle is about to pass through the branching portion 22, for example, when its own vehicle reaches a position where a time required for traveling to the branching portion 22 is less than a predetermined time.

The travel controller 33 is configured or programmed to transmit a state report including a merging portion passage permission request to the controller 4 before the merging portion 21 when its own vehicle is about to pass through the merging portion 21. The travel controller 33 is configured or programmed to transmit the merging portion passage permission request to the controller 4, for example, at a timing when a distance from its own vehicle to the merging portion 21 is a predetermined distance or less. The predetermined distance is set in advance, for example, and is 8 m, for example. The predetermined distance can be appropriately changed. The merging portion passage permission request is a signal for requesting permission of passage through the merging portion 21. When receiving a merging portion passage permission response from the controller 4, the travel controller 33 is configured or programmed to cause its own vehicle to enter the merging portion 21 by controlling the traveling unit. The merging portion passage permission response is a signal for permitting passage through the merging portion 21. When not receiving the merging portion passage permission response from the controller 4, the travel controller 33 is configured or programmed to control the traveling unit to cause its own vehicle to stop and wait at a stop point T before the merging portion 21. Note that the position where its own vehicle is caused to stop before its own vehicle passes through the merging portion 21 can be appropriately changed.

The travel controller 33 is configured or programmed to transmit a state report including a branching portion passage permission request to the controller 4 before the branching portion 22 when its own vehicle is about to pass through the branching portion 22. The branching portion passage permission request is a signal for requesting permission of passage through the branching portion 22. When receiving a branching portion passage permission response from the controller 4, the travel controller 33 is configured or programmed to cause its own vehicle to enter the branching portion 22 by controlling the traveling unit. The branching portion passage permission response is a signal for permitting passage through the branching portion 22. When not receiving the branching portion passage permission response from the controller 4, the travel controller 33 is configured or programmed to control the traveling unit to cause its own vehicle to stop and wait at a stop point T before the branching portion 22. Note that the position where its own vehicle is caused to stop before its own vehicle passes through the branching portion 22 can be appropriately changed.

The controller 4 may be an electronic controller including a CPU, a ROM, a RAM, and the like. The controller 4 can be configured, for example, as software in which a program stored in the ROM is loaded into the RAM and executed by the CPU. The controller 4 may be configured as hardware with an electronic circuit or the like.

The controller 4 is configured or programmed to include a transport vehicle controller 41, a congestion determiner 42, and a control switch 43. The transport vehicle controller 41 is configured or programmed to communicate with a plurality of transport vehicles 3 in its own control area and control the plurality of transport vehicles 3. The transport vehicle controller 41 is configured or programmed to communicate with the travel controllers 33 included in the transport vehicles 3 to control travel of the plurality of transport vehicles 3. The transport vehicle controller 41 is configured or programmed to communicate with a host controller (not illustrated) in a wired or wireless manner. For example, the transport vehicle controller 41 is configured or programmed to generate a transport command in response to a transport request given from the host controller, and assign the transport command to the transport vehicle 3.

The transport vehicle controller 41 is configured or programmed to perform periodic communication with the plurality of transport vehicles 3 in the control area. For example, the transport vehicle controller 41 is configured or programmed to transmit a state inquiry to a transport vehicle 3 in the control area, and receive a state report from the transport vehicle 3 that has received the state inquiry. By sequentially and periodically performing such communication with a plurality of transport vehicles 3 in the control area, the transport vehicle controller 41 grasps states of the plurality of transport vehicles 3 in the control area.

When causing the transport vehicle 3 to pass through the merging portion 21, the transport vehicle controller 41 is configured or programmed to execute blocking control to permit or prohibit passage of the transport vehicle 3 through the merging portion 21. Specifically, in a case where the transport vehicle controller 41 receives a merging portion passage permission request related to the merging portion 21 from a transport vehicle 3, when a merging lock area RG for an area including the merging portion 21 is not set, the transport vehicle controller 41 is configured or programmed to transmit a merging portion passage permission response to the transport vehicle 3 and permits passage of the transport vehicle 3 through the merging portion 21. The transport vehicle controller 41 is configured or programmed to permit passage of the transport vehicle 3 and sets the merging lock area RG. The merging lock area RG is an area for prohibiting a transport vehicle 3 that has not received a merging portion passage permission response from entering a blocking area (not illustrated) including the merging portion 21.

The transport vehicle controller 41 is configured or programmed to release the merging lock area RG after the transport vehicle 3 that has passed through the merging portion 21 passes a post-merging point. The post-merging point is a point on a downstream side of the merging portion 21 (a point on the track 2). The post-merging point is, for example, a position set by using a predetermined point mark located on a downstream side of the merging portion 21 as a reference. In the present example embodiment, the post-merging point is set by using a point mark at a position closest to the merging portion 21 on a downstream side of the merging portion 21 as a reference. In a case where the transport vehicle controller 41 receives a merging portion passage permission request related to the merging portion 21 from a transport vehicle 3, when a merging lock area RG is set, the transport vehicle controller 41 does not transmit a merging portion passage permission response to the transport vehicle 3 and causes the transport vehicle 3 to wait at a stop point I.

The transport vehicle controller 41 is configured or programmed to execute either priority control or non-priority control. In the priority control, the transport vehicle controller 41 sets one of the first route R1 and the second route R2 as a priority route. The priority control is control to cause a transport vehicle 3 traveling on one of the first route R1 and the second route R2 set as the priority route to preferentially pass through the merging portion 21 with respect to a transport vehicle 3 traveling on the other route. A method by which the transport vehicle controller 41 sets the priority route will be described later. The non-priority control is control to cause the transport vehicle 3 to pass through the merging portion 21 without giving priority depending on whether the transport vehicle 3 is traveling on the first route R1 or the second route R2. “Not giving priority” means, for example, not giving priority to a transport vehicle 3 that is caused to pass through the merging portion 21. In other words, the non-priority control is control to determine whether or not to permit passage of a transport vehicle 3 traveling on one of the first route R1 and the second route R2 and a transport vehicle 3 traveling on the other route through the merging portion 21 on an equal basis regarding a traveling route. In the present example embodiment, in the non-priority control, a transport vehicle 3 traveling on the first route R1 and a transport vehicle 3 traveling on the second route R2 are caused to alternately pass through the merging portion 21. Details of the priority control and the non-priority control will be described later.

The congestion determiner 42 is configured or programmed to determine whether or not congestion of the transport vehicle 3 occurs in predetermined determination target areas 61 and 62 (see FIG. 1) located on an upstream side of the merging portion 21 on the first route R1 or the second route R2. In the present example embodiment, each Of the determination target areas 61 and 62 (hereinafter, also referred to as a “determination target area”) is set within a range within, for example, 15 m from the merging portion 21 on an upstream side of the merging portion 21. The determination target areas and 62 are set in advance, for example, and may be appropriately changed. Each of the lengths of the determination target areas 61 and 62 may be set by using, for example, the predetermined distance used for stop control by the travel controller 33 as a reference. Each of the lengths of the determination target areas 61 and 62 may be, for example, an integral multiple of the predetermined distance, or may be set to a length obtained by adding a length of a predetermined number (threshold) (described later) of transport vehicles 3 to an integral multiple of the predetermined distance.

The determination target area 61 is set on the first route R1. The determination target area 61 includes a connecting route 51 included in the first route R1 and a plurality of merging routes 52. The determination target area 62 is set on the second route R2. The determination target area 62 includes a portion located on an upstream side of the merging portion 21a in the third linear route 29 included in the second route R2.

The congestion determiner 42 determines whether or not congestion of the transport vehicle 3 occurs in the determination target area. In the present example embodiment, the congestion determiner 42 is configured or programmed to determine that, when there are a predetermined number or more of transport vehicles 3 whose distances from transport vehicles 3 located in front of their own vehicles are each a predetermined distance or less in the determination target area, congestion of the transport vehicle 3 occurs in the determination target area. The predetermined number is, for example, a threshold set in advance, and can be appropriately changed. The congestion determiner 42 is configured or programmed to determine that, when there are a predetermined number or more of transport vehicles 3 stopped under control of the travel controller 33 in the determination target area, congestion of the transport vehicle 3 occurs in the determination target area.

The congestion determiner 42 is configured or programmed to periodically determine whether or not there are a predetermined number or more of transport vehicles 3 stopped under control of the travel controller 33 in the determination target area on the basis of a state report periodically transmitted from the travel controller 33. The cycle is, for example, 10 seconds, but can be appropriately changed. The cycle is set in advance, for example. The congestion determiner 42 is configured or programmed to perform the congestion determination on the basis of position information included in the state report and information indicating that stop control is being executed.

The control switch 43 is configured or programmed to switch control executed by the transport vehicle controller 41 on the basis of a determination result of the congestion determiner 42. When the congestion determiner 42 determines that congestion of the transport vehicle 3 occurs in the determination target area, the control switch 43 switches control such that the transport vehicle controller 41 executes non-priority control. When the congestion determiner 42 determines that congestion of the transport vehicle 3 does not occur in the determination target area, the control switch 43 switches control such that the transport vehicle controller 41 executes priority control.

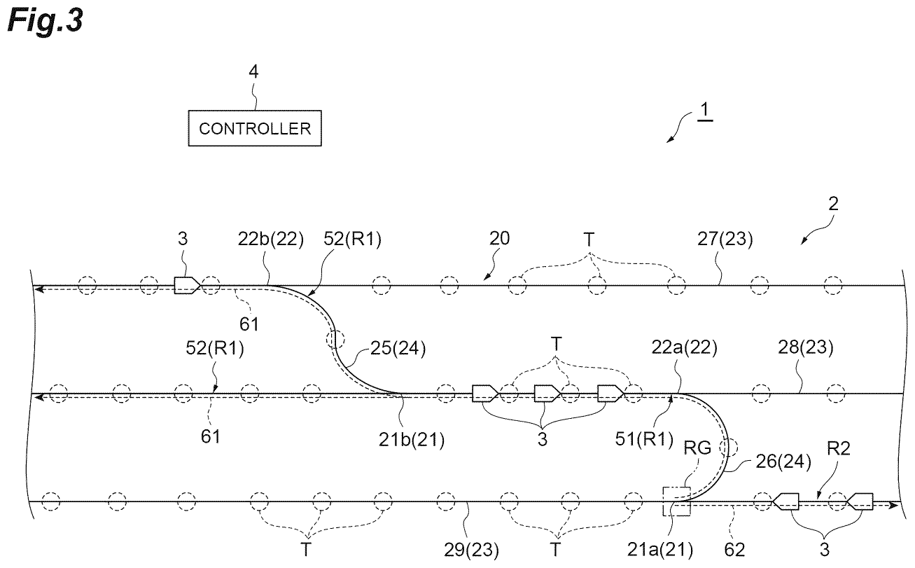

Subsequently, an operation of the transport system 1 according to the present example embodiment will be described with reference to FIGS. 3 to 9. In the state illustrated in FIG. 3, description will be given by assuming that the transport vehicle controller 41 is executing non-priority control.

First, the congestion determiner 42 determines whether or not congestion of the transport vehicle 3 occurs in the determination target area. The congestion determiner 42 determines that, when there are a predetermined number (the above threshold) or more of transport vehicles 3 stopped under control of the travel controller 33 in the determination target area, congestion of the transport vehicle 3 does not occur in the determination target area. In the example illustrated in FIG. 3 and subsequent drawings, the threshold is set to six. In FIG. 3, the number of transport vehicles 3 stopped under control of the travel controller 33 in the determination target area 61 is three. In addition, the number of transport vehicles 3 stopped under control of the travel controller 33 in the determination target area 62 is two. Therefore, as a result of the congestion determination periodically executed by the congestion determiner 42, the congestion determiner 42 determines that congestion of the transport vehicle 3 does not occur in the determination target area.

Subsequently, the control switch 43 switches control executed by the transport vehicle controller 41 on the basis of a determination result of the congestion determiner 42. Specifically, since the congestion determiner 42 determines that congestion of the transport vehicle 3 does not occur in the determination target area, the control switch 43 switches control such that the transport vehicle controller 41 executes priority control.

Hereinafter, in the priority control, a transport vehicle 3 that travels on one of the first route R1 and the second route R2 and preferentially passes through the merging portion 21 with respect to a transport vehicle 3 traveling on the other route is referred to as a priority transport vehicle 3a, and the transport vehicle 3 traveling on the other route is referred to as a standby transport vehicle 3b. Of the first route R1 and the second route R2, a route on which the priority transport vehicle 3a travels is referred to as a “priority route”, and a route on which the standby transport vehicle 3b travels is referred to as a “standby route”.

When the control switch 43 switches control executed by the transport vehicle controller 41 from the non-priority control to the priority control, the transport vehicle controller 41 sets one of the first route R1 and the second route R2 as the priority route and sets the other route as the standby route. For example, the transport vehicle controller 41 sets, among the first route R1 and the second route R2, the one on which the transport vehicle 3 that has received the merging portion passage permission request earliest after the timing at which the control switch 43 switches the control travels as the priority route, and sets the other as the standby route. Hereinafter, an example in which the transport vehicle controller 41 sets the first route R1 as the priority route and sets the second route R2 as the standby route will be described.

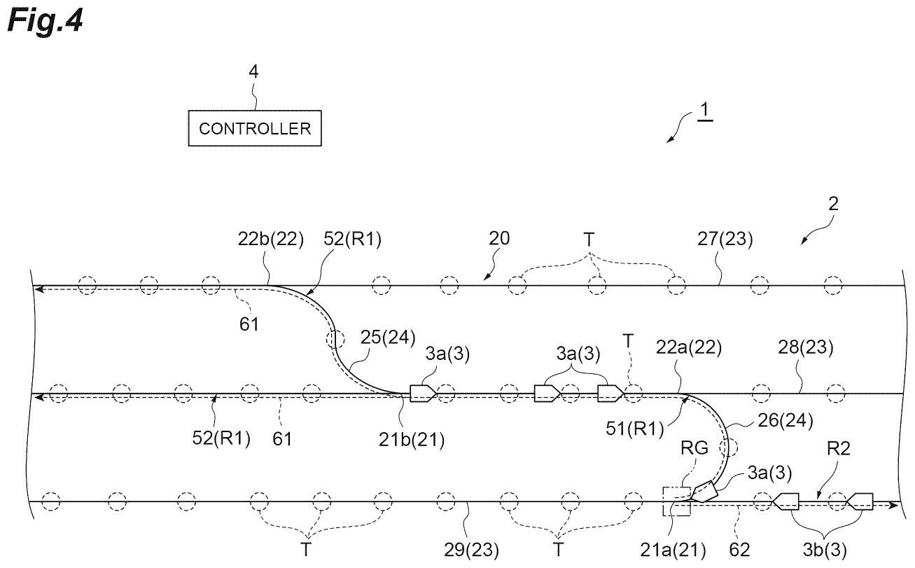

As illustrated in FIG. 4, when receiving a merging portion passage permission request from the priority transport vehicle 3a, the transport vehicle controller 41 transmits a merging portion passage permission response to the priority transport vehicle 3a, permits passage of the priority transport vehicle 3a, and sets a merging lock area RG. The transport vehicle controller 41 releases the merging lock area RG after the priority transport vehicle 3a passes a post-merging point. The transport vehicle controller 41 repeatedly executes similar control until a predetermined time elapses after the control switch 43 switches the control and first receives the merging portion passage permission request. The predetermined time is set in advance, for example, and can be appropriately changed. Until the predetermined time elapses, the transport vehicle controller 41 does not transmit a merging portion passage permission response to the standby transport vehicle 3b, and causes the standby transport vehicle 3b to wait at a stop point T. As a result, the priority transport vehicle 3a traveling on the first route R1 continuously passes through the merging portion 21.

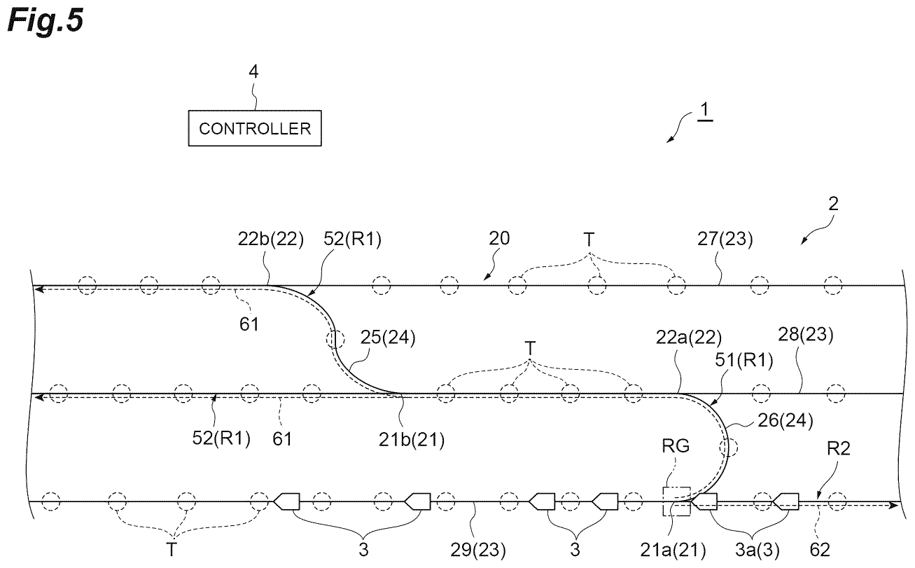

At a timing when the predetermined time has elapsed, the transport vehicle controller 41 sets the first route R1 set as the priority route as the standby route, and sets the second route R2 set as the standby route as the priority route. The transport vehicle controller 41 repeatedly executes the above control, whereby the priority transport vehicle 3a traveling on the second route R2 continuously passes through the merging portion 21 as illustrated in FIG. 5. The transport vehicle controller 41 alternately switches the priority route and the standby route therebetween every time the predetermined time elapses.

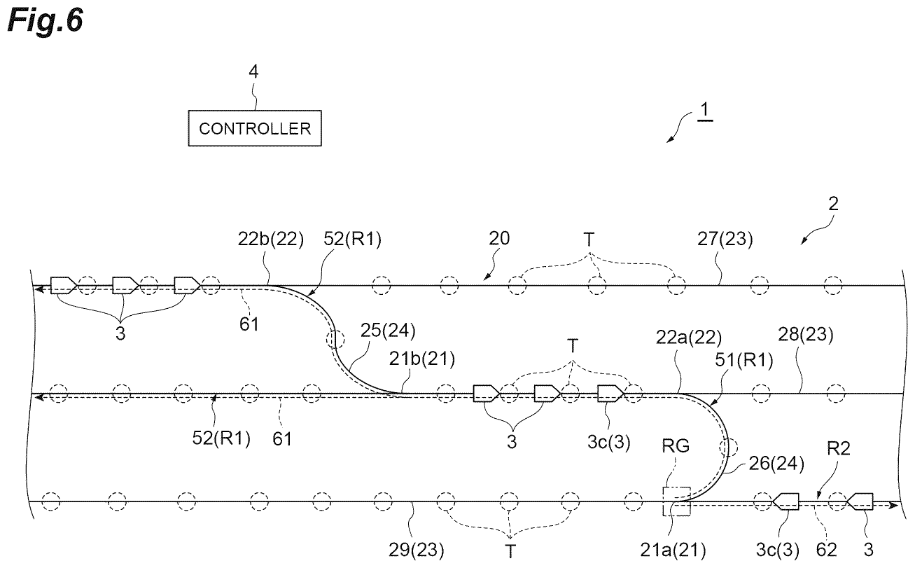

Subsequently, an operation when congestion of the transport vehicle 3 occurs in the determination target area will be described. In the state illustrated in FIG. 6, description will be given by assuming that the transport vehicle controller 41 is executing priority control.

In FIG. 6, the number of transport vehicles 3 stopped under control of the travel controller 33 in the determination target area 61 is six, for example. Therefore, as a result of the congestion determination periodically executed by the congestion determiner 42, the congestion determiner 42 determines that congestion of the transport vehicle 3 occurs in the determination target area. Subsequently, since the congestion determiner 42 determines that congestion of the transport vehicle 3 occurs in the determination target area, the control switch 43 switches control such that the transport vehicle controller 41 executes non-priority control.

Hereinafter, in the non-priority control, a transport vehicle 3 located on an upstream side of the merging portion 21 in each of the first route R1 and the second route R2 and closest to the merging portion 21 is referred to as a head transport vehicle 3c. When the control switch 43 switches control executed by the transport vehicle controller 41 from the priority control to the non-priority control, the transport vehicle controller 41 transmits a merging portion passage permission response to either a head transport vehicle 3c on the first route R1 or a head transport vehicle 3c on the second route R2. For example, the transport vehicle controller 41 transmits the merging portion passage permission response to a head transport vehicle 3c on a route in which a determination target area determined to have congestion by the congestion determiner 42 is set, of the first route R1 and the second route R2. In the example of FIG. 6, an example in which the transport vehicle controller 41 transmits the merging portion passage permission response to a head transport vehicle 3c on the first route R1 when the control switch 43 switches the control will be described.

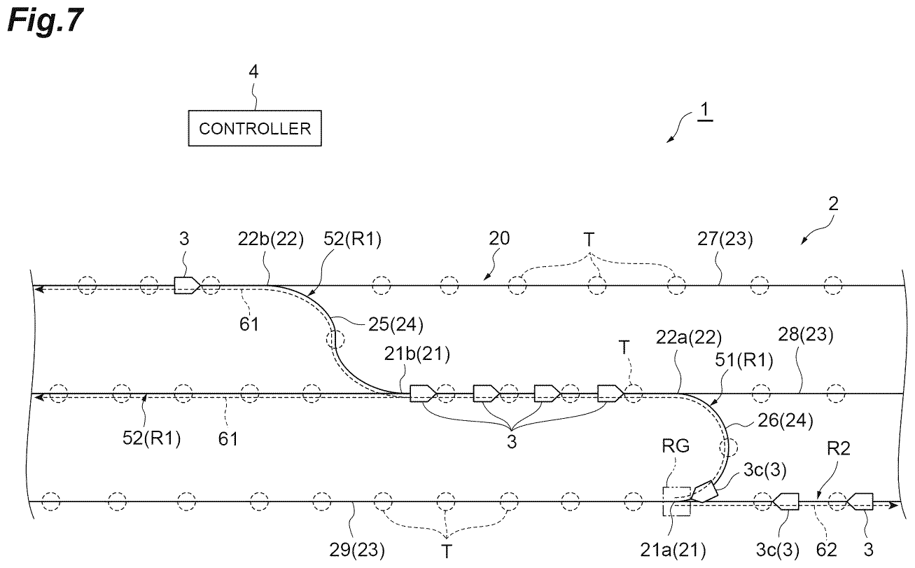

As illustrated in FIG. 7, when receiving a merging portion passage permission request from a head transport vehicle 3c on the first route R1, the transport vehicle controller 41 transmits a merging portion passage permission response to the head transport vehicle 3c, permits passage of the head transport vehicle 3c, and sets a merging lock area RG. The transport vehicle controller 41 releases the merging lock area RG after the head transport vehicle 3c passes a post-merging point. The transport vehicle controller 41 does not transmit the merging portion passage permission response to a head transport vehicle 3c on the second route R2 and causes the head transport vehicle 3c on the second route R2 to wait at a stop point T until a head transport vehicle 3c on the first route R1 passes the post-merging point.

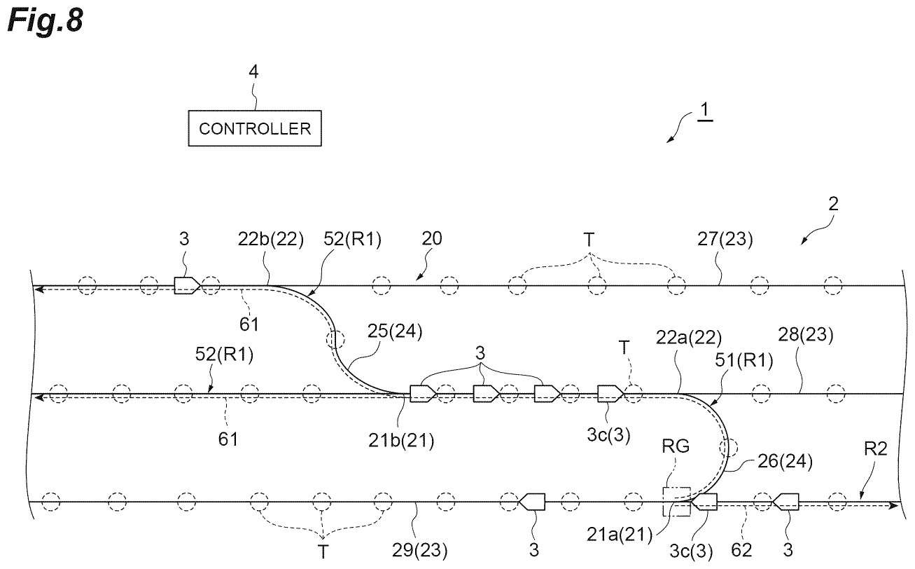

Next, as illustrated in FIG. 8, when receiving a merging portion passage permission request from the head transport vehicle 3c on the second route R2, the transport vehicle controller 41 transmits a merging portion passage permission response to the head transport vehicle 3c, permits passage of the head transport vehicle 3c, and sets a merging lock area RG. The transport vehicle controller 41 releases the merging lock area RG after the head transport vehicle 3c passes a post-merging point. The transport vehicle controller 41 does not transmit the merging portion passage permission response to a head transport vehicle 3c on the first route R1 and causes the head transport vehicle 3c on the first route R1 to wait at a stop point T until a head transport vehicle 3c on the second route R2 passes the post-merging point.

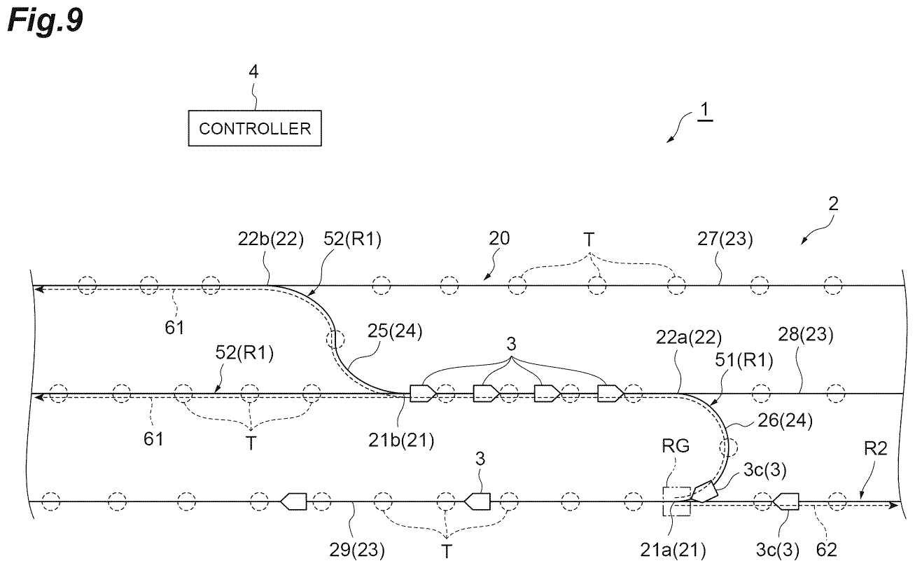

Subsequently, as illustrated in FIG. 9, the transport vehicle controller 41 repeats similar processing to cause a head transport vehicle 3c traveling on the first route R1 and a head transport vehicle 3c traveling on the second route R2 to alternately pass through the merging portion 21 one by one.

In the transport system 1 according to the present example embodiment, when congestion of the transport vehicle 3 occurs in the determination target area, the transport vehicle controller 41 included in the controller 4 executes non-priority control. In the non-priority control, the transport vehicle 3 is caused to pass through the merging portion 21 without being prioritized depending on a travel route on which the transport vehicle 3 travels, and therefore it is possible to eliminate congestion of the transport vehicle 3 in the determination target area (see FIGS. 6 to 9). For example, when heavy congestion occurs in the determination target area, the control to cause the transport vehicle 3 to pass through the merging portion 21 can be automatically switched from priority control to non-priority control, and therefore a time for alleviating the congestion can be shortened. In order to prevent a standby time of the transport vehicle 3 on an upstream side of the merging portion 21 from becoming excessive, it is conceivable to set a limit on the standby time and to execute DLE when the standby time is a predetermined time or longer. Even in this case, since the standby transport vehicle 3 can move forward relatively early, a frequency of executing DLE can be reduced.

In addition, in this transport system 1, when congestion of the transport vehicle 3 does not occur in the determination target area, the transport vehicle controller 41 included in the controller 4 executes the priority control. In the priority control, one transport vehicle 3 traveling on one of the first route R1 and the second route R2 set as a priority route preferentially passes through the merging portion 21 with respect to the other transport vehicle 3 traveling on the other route (see FIGS. 3 to 5). As a result, when one transport vehicle 3 passes through the merging portion 21, the transport vehicle 3 does not need to wait until the other transport vehicle 3 passes through the merging portion 21. As a result, one transport vehicle 3 can pass through the merging portion 21 without repeating starting and stopping. From the above, transport efficiency can be improved.

In the non-priority control, a transport vehicle 3 traveling on the first route R1 and a transport vehicle 3 traveling on the second route R2 are caused to alternately pass through the merging portion 21 (see FIGS. 6 to 9). As a result, by causing a transport vehicle 3 traveling on the first route R1 and a transport vehicle 3 traveling on the second route R2 to alternately pass through the merging portion 21, it is possible to reliably eliminate congestion of the transport vehicle 3 in the determination target area.

The congestion determiner 42 included in the controller 4 determines that, when there are a predetermined number or more of transport vehicles 3 whose distances from transport vehicles 3 located in front of their own vehicles are each a predetermined distance or less in the determination target area, congestion of the transport vehicle 3 occurs in the determination target area. As a result, presence or absence of congestion of the transport vehicle 3 can be determined on the basis of the number of transport vehicles 3 approaching each other in the determination target area (see FIG. 3). As a result, it is possible to easily determine congestion of the transport vehicle 3 in the determination target area.

The transport vehicle 3 includes the distance calculator 32 that measures a distance to a transport vehicle 3 located in front of its own vehicle, and the travel controller 33 that causes its own vehicle to stop when the distance is a predetermined distance or less. The congestion determiner 42 included in the controller 4 determines that, when there are a predetermined number or more of transport vehicles 3 stopped under control of the travel controller 33 in the determination target area, congestion of the transport vehicle 3 occurs in the determination target area. In this case, presence or absence of congestion of the transport vehicle 3 can be determined on the basis of the number of transport vehicles 3 stopped under control of the travel controller 33 in the determination target area (see FIG. 6). As a result, it is possible to more easily determine congestion of the transport vehicle 3 in the determination target area.

The determination target area 61 includes the connecting route 51 connected to the merging portion 21 and a plurality of merging routes 52 merging into the connecting route 51 (see FIG. 1). For example, when the connecting route 51 does not have a sufficient length, it may be difficult to determine presence or absence of congestion only from a travel situation on the connecting route 51. By considering not only the connecting route 51 but also the number of transport vehicles 3 in the plurality of merging routes 52 and the like, it is possible to accurately determine congestion regardless of a layout of the travel route.

Although some example embodiments of the present disclosure have been described above, the present disclosure is not limited to the above example embodiments. For example, in the non-priority control, a predetermined number of (two or more) transport vehicles 3 traveling on the first route R1 and a predetermined number of (two or more) transport vehicles 3 traveling on the second route R2 may be caused to alternately pass through the merging portion 21. The predetermined number is set in advance, for example, and can be appropriately changed. In this case, the transport vehicle controller 41 only needs to repeatedly execute control to cause the head transport vehicle 3c on the first route R1 to pass through the merging portion 21, and only needs to repeatedly execute control to cause the head transport vehicle 3c on the second route R2 to pass through the merging portion 21 after a predetermined number of transport vehicles 3 pass through the merging portion 21.

The non-priority control only needs to be control to cause the transport vehicle 3 to pass through the merging portion 21 without giving priority depending on whether the transport vehicle 3 is traveling on the first route R1 or the second route R2, and various controls may be adopted as the non-priority control. In the non-priority control, the transport vehicle controller 41 may cause a transport vehicle 3 that transports an article to a specific transport destination to preferentially pass through the merging portion 21 with respect to a transport vehicle 3 that transports an article to a transport destination other than the specific transport destination on the basis of a transport command. In this case, for example, it is possible to quickly transport an article to a specific transport destination having a higher demand for the article than other transport destinations.

In the above example embodiments, at a timing when a predetermined time has elapsed after the control switch 43 switches control and first receives a merging portion passage permission request, the transport vehicle controller 41 sets the first route R1 set as the priority route as the standby route, and sets the second route R2 set as the standby route as the priority route. However, at a timing when it is determined that a predetermined condition (hereinafter, referred to as a “switching condition”) is satisfied, the transport vehicle controller 41 may set the route set as the priority route as the standby route, and may set the route set as the standby route as the priority route. Hereinafter, an example of the switching condition will be described.

The switching condition includes, for example, that all the priority transport vehicles 3a transmitting a merging portion passage permission request to the transport vehicle controller 41 at a predetermined timing have passed a post-merging point, and a merging lock area RG has been released (hereinafter, referred to as a “first condition”). The predetermined timing is set in advance, for example, and can be appropriately changed. As an example, the predetermined timing is a timing when a predetermined time has elapsed without the transport vehicle controller 41 newly receiving a merging portion passage permission request from the priority transport vehicle 3a. In this case, for example, the travel controller 33 transmits a merging portion passage permission request including identification information which is information for uniquely specifying its own vehicle to the transport vehicle controller 41. On the basis of the identification information, the transport vehicle controller 41 specifies the priority transport vehicle 3a transmitting the merging portion passage permission request to the transport vehicle controller 41 at a timing when the predetermined time has elapsed. When all the specified priority transport vehicles 3a have passed the post-merging point and the transport vehicle controller 41 has released the merging lock area RG, the transport vehicle controller 41 determines that the first condition is satisfied.

The switching condition includes, for example, that the number of standby transport vehicles 3b that have transmitted a merging portion passage permission request to the transport vehicle controller 41 and are waiting at a stop point T is larger than a predetermined number (hereinafter, referred to as a “second condition”). The predetermined number is set in advance, for example, and can be appropriately changed. The predetermined number is, for example, 3. In this case, for example, on the basis of the identification information, the transport vehicle controller 41 specifies a standby transport vehicle 3b that has transmitted the merging portion passage permission request to the transport vehicle controller 41 and is waiting at a stop point T. When the transport vehicle controller 41 receives a new merging portion passage permission request from a standby transport vehicle 3b other than the specified standby transport vehicle 3b in a state where the number of the specified standby transport vehicles 3b is a predetermined number, the transport vehicle controller 41 determines that the second condition is satisfied.

The switching condition includes, for example, that a predetermined time elapses after the control switch 43 switches control and the transport vehicle controller 41 first receives the merging portion passage permission request (hereinafter, referred to as a “third condition”). In this case, when a predetermined time elapses after the control switch 43 switches the control and first receives the merging portion passage permission request, the transport vehicle controller 41 determines that the third condition is satisfied. For example, the transport vehicle controller 41 may use a condition that all of the first condition, the second condition, and the third condition are satisfied as the switching condition.

For example, the transport vehicle controller 41 may use only any one of the first condition, the second condition, and the third condition as the switching condition. In addition, for example, the transport vehicle controller 41 may use an appropriate combination of the first condition, the second condition, and the third condition as the switching condition. In this case, for example, the transport vehicle controller 41 may determine that the switching condition is satisfied when determining that any one of the first condition, the second condition, and the third condition is satisfied, or may determine that the switching condition is satisfied when determining that two or more of the first condition, the second condition, and the third condition are satisfied. Note that the content of the switching condition is merely an example, and can be appropriately changed without departing from the gist of the present disclosure.

In addition, in a case where at least one of the second condition and the third condition is used as the switching condition, even when determining that the second condition or the third condition is satisfied, the transport vehicle controller 41 may determine not to execute switching between the priority route and the standby route until all the priority transport vehicles 3a that have transmitted the merging portion passage permission response pass a post-merging point and the transport vehicle controller 41 sets a merging lock area RG.

In the above example embodiments, the congestion determiner 42 determines whether or not congestion of the transport vehicle 3 occurs in each of the determination target areas 61 and 62. However, the congestion determiner 42 may determine whether or not congestion of the transport vehicle 3 occurs only in a determination target area set on the non-priority route without determining whether or not congestion of the transport vehicle 3 occurs in a determination target area set on the priority route.

In the above example embodiments, the travel controller 33 causes its own vehicle to stop when a distance measured by the distance calculator 32 is a predetermined distance or less. However, the present invention is not limited to this control, and when a distance measured by the distance calculator 32 is a predetermined distance or less (when two transport vehicles 3 are approaching each other), the travel controller 33 may perform control to cause its own vehicle (that is, a rear transport vehicle 3 of the two transport vehicles 3) to travel at a very low travel speed (decelerate). In this case, an emergency stop distance shorter than the predetermined distance may be set.

In the above example embodiments, an overhead traveling unmanned traveling vehicle is used as the transport vehicle 3, but the transport vehicle 3 is not particularly limited. The transport vehicle 3 may be an overhead traveling shuttle. The transport vehicle 3 may be a tracked unmanned transport carriage capable of traveling along a track on a floor. The transport vehicle 3 may be a magnetic induction type unmanned transport vehicle capable of traveling along a route formed of a magnetic tape or the like. The transport vehicle 3 may be a laser-guided unmanned transport carriage capable of traveling along a predetermined route by being guided by laser light.

In the above example embodiments, one or more other controllers configured or programmed to relay signals or instructions or requests to the controller 4 to the transport vehicle 3 may be included.

Example embodiments of the present disclosure may include the following.

A transport system including a plurality of transport vehicles configured to travel on a travel route and transport an article, and a controller configured or programmed to control travel of the plurality of transport vehicles, wherein the travel route includes a first route, a second route different from the first route, and a merging portion where the first route and the second route merge, the controller is configured or programmed to execute one of priority control to cause one of the plurality of transport vehicles traveling on one of the first route and the second route set as a priority route to preferentially pass through the merging portion with respect to another of the plurality of transport vehicles traveling on the other route, and non-priority control to cause the one of the plurality of transport vehicles to pass through the merging portion without giving priority depending on whether the one of the plurality of transport vehicles is traveling on the first route or the second route, and the controller is configured or programmed to execute the non-priority control when congestion of the one of the plurality of transport vehicles occurs in a predetermined determination target area located on an upstream side of the merging portion in the first route or the second route, and execute the priority control when congestion of the one of the plurality of transport vehicles does not occur in the determination target area.

The transport system according to [1], wherein in the non-priority control, the transport vehicle traveling on the first route and the transport vehicle traveling on the second route are caused to alternately pass through the merging portion.

The transport system according to [1] or [2], wherein the controller is configured or programmed to determine, when there are a predetermined number or more of the plurality of transport vehicles spaced from the transport vehicles located in front thereof each at a predetermined distance or less in the determination target area, that congestion of the transport vehicle occurs in the determination target area.

The transport system according to [3], wherein one of the plurality of transport vehicles includes a distance calculator configured or programmed to measure a distance to another one of the plurality of transport vehicles located in front of the one of the plurality of transport vehicles, and a travel controller configured or programmed to cause the one of the plurality of transport vehicles to stop when the distance is a predetermined distance or less, and the controller is configured or programmed to determine, when there are a predetermined number or more of the plurality of transport vehicles stopped under control of the travel controller in the determination target area, that congestion of the transport vehicle occurs in the determination target area.

The transport system according to any one of [1] to [4], wherein the determination target area includes a connecting route connected to the merging portion, and a plurality of merging routes merging into the connecting route.

While example embodiments of the present invention have been described above, it is to be understood that variations and modifications will be apparent to those skilled in the art without departing from the scope and spirit of the present invention. The scope of the present invention, therefore, is to be determined solely by the following claims.

1-5. (canceled)

6. A transport system comprising:
a plurality of transport vehicles configured to travel on a travel route and transport an article; and
a controller configured or programmed to control travel of the plurality of transport vehicles; wherein
the travel route includes a first route, a second route different from the first route, and a merging portion where the first route and the second route merge;
the controller is configured or programmed to execute one of:
priority control to cause one of the plurality of transport vehicles traveling on one of the first route and the second route set as a priority route to preferentially pass through the merging portion with respect to another of the plurality of transport vehicles traveling on the other route; and
non-priority control to cause the one of the plurality of transport vehicles to pass through the merging portion without giving priority depending on whether the one of the plurality of transport vehicles is traveling on the first route or the second route; and
the controller is configured or programmed to:
execute the non-priority control when congestion of the one of the plurality of transport vehicles occurs in a predetermined determination target area located on an upstream side of the merging portion in the first route or the second route; and
execute the priority control when congestion of the one of the plurality of transport vehicles does not occur in the determination target area.

7. The transport system according to claim 6, wherein, in the non-priority control, the transport vehicle traveling on the first route and the transport vehicle traveling on the second route are caused to alternately pass through the merging portion.

8. The transport system according to claim 6, wherein the controller is configured or programmed to determine, when there are a predetermined number or more of the plurality of transport vehicles spaced from the transport vehicles located in front thereof each at a predetermined distance or less in the determination target area, that congestion of the transport vehicle occurs in the determination target area.

9. The transport system according to claim 8, wherein
one of the plurality of transport vehicles includes:
a distance calculator configured or programmed to measure a distance to another one of the plurality of transport vehicles located in front of the one of the plurality of transport vehicles; and
a travel controller configured or programmed to cause the one of the plurality of transport vehicles to stop when the distance is a predetermined distance or less; and
the controller is configured or programmed to determine, when there are a predetermined number or more of the plurality of transport vehicles stopped under control of the travel controller in the determination target area, that congestion of the transport vehicle occurs in the determination target area.

10. The transport system according to claim 6, wherein
the determination target area includes:
a connecting route connected to the merging portion; and
a plurality of merging routes merging into the connecting route.
